(19) United States
(12) Patent Application Publication
(10) Pub. No.: US 2026/0020146 A1
(43) Pub. Date: Jan. 15, 2026

(54) WIRING CIRCUIT BOARD

(71) Applicant: NITTO DENKO CORPORATION, Osaka (JP)

(72) Inventors: Takashi YAMAMOTO, Osaka (JP); Ryosuke SASAOKA, Osaka (JP)

(73) Assignee: NITTO DENKO CORPORATION, Osaka (JP)

(21) Appl. No.: 19/261,515

(22) Filed: Jul. 7, 2025

(30) Foreign Application Priority Data
Jul. 11, 2024 (JP) 2024-111871

(51) Int. Cl. H05K 1/02; H05K 1/05

(52) U.S. Cl. CPC H05K 1/0271; H05K 1/0207; H05K 1/056; H05K 2201/0154; H05K 2201/09381

(57) ABSTRACT

A wiring circuit board includes a metal support layer, a first insulating layer, a terminal, and a heat dissipating layer. The first insulating layer is made of polyimide and has a water absorption rate of 0.40% or more. The heat dissipating layer is disposed on an opposite side to the terminal with respect to the first insulating layer, and is disposed between the metal support layer and the first insulating layer. The heat dissipating layer is in contact with both the metal support layer and the first insulating layer.

### CROSS-REFERENCE TO RELATED APPLICATION

The present application claims priority from Japanese Patent Application No. 2024-111871 filed on Jul. 11, 2024, the content of which is hereby incorporated by reference into this application.

### TECHNICAL FIELD

The present invention relates to a wiring circuit board.

### BACKGROUND ART

Conventionally, there has been a known wiring circuit board including a metal support layer, a base insulating layer disposed on a one-side surface of the metal support layer in the thickness direction, and a conductive pattern disposed on a one-side surface of the base insulating layer in the thickness direction (for example, see Patent Document 1 below).

### CITATION LIST

### Patent Document

Patent Document 1: Japanese Unexamined Patent Publication No. 2023-171201

### SUMMARY OF THE INVENTION

### Problem to be Solved by the Invention

In the wiring circuit board as described in Patent Document 1, when the base insulating layer has a high water absorption rate, and the heat of molten solder is transferred to the base insulating layer through the terminal of the conductive pattern, a void is generated due to the volatilization of moisture in the base insulating layer. Thus, there is a problem that the base insulating layer is easily released from the metal support layer.

The present invention provides a wiring circuit board capable of suppressing the release of the insulating layer from the metal support layer even when the insulating layer has a high water absorption rate.

### Means for Solving the Problem

The present invention [1] includes a wiring circuit board including: a metal support layer; an insulating layer disposed on one side of the metal support layer in a thickness direction of the metal support layer, the insulating layer being made of polyimide, and the insulating layer having a water absorption rate of 0.40% or more; a terminal disposed on a one-side surface of the insulating layer in the thickness direction; and a heat dissipating layer disposed on an opposite side to the terminal with respect to the insulating layer in the thickness direction, the heat dissipating layer being disposed between the metal support layer and the insulating layer in the thickness direction, and the heat dissipating layer being in contact with both the metal support layer and the insulating layer.

According to such a configuration, a heat dissipating layer is provided between the metal support layer and the insulating layer.

Therefore, when the heat of molten solder is transferred to the insulating layer through the terminal, the heat transferred to the insulating layer can be diffused into the heat dissipating layer, and can be transferred to the metal support layer through the heat dissipating layer. In this manner, it is possible to suppress the accumulation of the heat of molten solder in the insulating layer.

As a result, even when the insulating layer has a high water absorption rate, the release of the insulating layer from the metal support layer can be suppressed.

The present invention [2] includes the wiring circuit board described in the above-described [1], wherein an area of the heat dissipating layer is larger than or equal to an area of the terminal in a direction orthogonal to the thickness direction.

According to such a configuration, the heat transferred to the insulating layer through the terminal can be reliably diffused into the heat dissipating layer.

The present invention [3] includes the wiring circuit board described in the above-described [1] or [2], wherein a thermal conductivity of the heat dissipating layer is higher than a thermal conductivity of the metal support layer.

According to such a configuration, the heat transferred to the insulating layer through the terminal can be smoothly diffused into the heat dissipating layer.

The present invention [4] includes the wiring circuit board described in any one of the above-described [1] to [3], wherein the heat dissipating layer has a thickness of 0.5 μm or more.

According to such a configuration, the volume of the heat dissipating layer can be ensured.

Therefore, the heat transferred to the insulating layer through the terminal can be reliably diffused into the heat dissipating layer.

The present invention [5] includes the wiring circuit board described in any one of the above-described [1] to [4], wherein the insulating layer has a thickness of 50 μm or less between the terminal and the heat dissipating layer.

According to such a configuration, it is possible to suppress the accumulation of the heat of molten solder in the insulating layer, and to smoothly diffuse the heat transferred to the insulating layer through the terminal into the heat dissipating layer.

The present invention [6] includes the wiring circuit board described in any one of the above-described [1] to [5], wherein a ratio of the area of the terminal in the direction orthogonal to the thickness direction to a thickness of the insulating layer is 5000 μm or more.

According to such a configuration, it is possible to suppress the accumulation of the heat of molten solder in the insulating layer, and to smoothly diffuse the heat transferred to the insulating layer through the terminal into the heat dissipating layer.

### Effects of the Invention

According to the wiring circuit board of the present invention, the release of the insulating layer from the metal support layer can be suppressed even when the insulating layer has a high water absorption rate.

### BRIEF DESCRIPTION OF THE DRAWINGS

FIG. 1 shows a plan view of one embodiment of the wiring circuit board of the present invention.

FIG. 2 is a cross-sectional view of the wiring circuit board shown in FIG. 1, taken along line A-A.

FIGS. 3A to 3D show the steps of producing the wiring circuit board shown in FIG. 2,

FIG. 3A shows a heat dissipating layer forming step, FIG. 3B shows a first insulating layer forming step, FIG. 3C shows a step of forming a first conductor layer of a terminal and a wire in a conductive pattern forming step, and FIG. 3D shows a step of forming a second conductor layer of the terminal in the conductive pattern forming step.

### DESCRIPTION OF THE EMBODIMENT

### 1. Wiring Circuit Board

As shown in FIG. 1, a wiring circuit board 1 extends in a first direction and a second direction. The second direction is orthogonal to the first direction. The shape of the wiring circuit board 1 is not limited. The wiring circuit board 1 may be a flexible wiring circuit board or a suspension board with circuit.

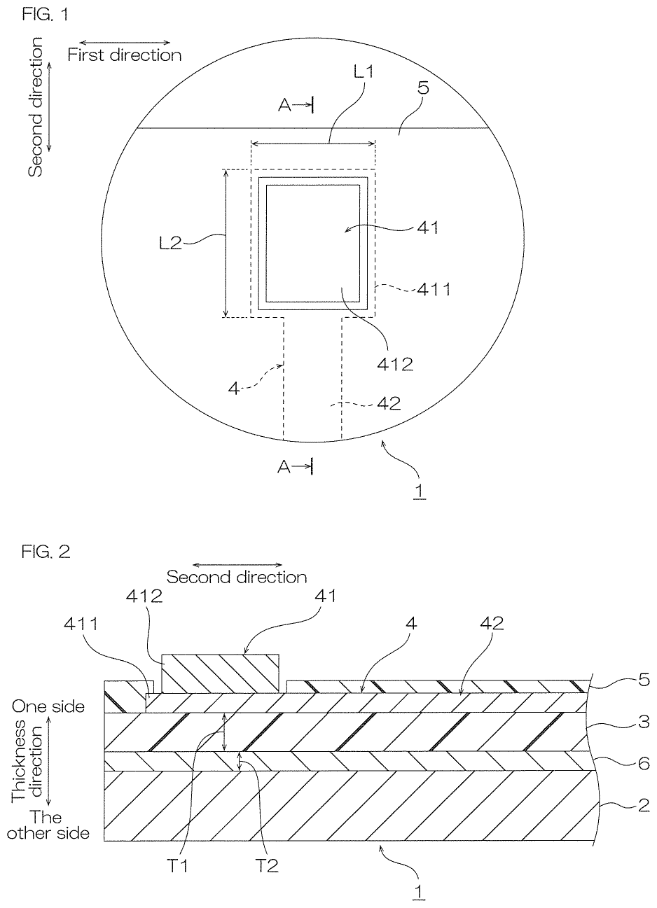

As shown in FIG. 2, the wiring circuit board 1 includes a metal support layer 2, a first insulating layer 3 as an example of an insulating layer, a conductive pattern 4, a second insulating layer 5, and a heat dissipating layer 6.

### (1) Metal Support Layer

The metal support layer 2 supports the first insulating layer 3, the conductive pattern 4, the second insulating layer 5, and the heat dissipating layer 6. Examples of the material of the metal support layer 2 include stainless steel and a copper alloy. The metal support layer 2 is preferably made of a copper alloy.

The metal support layer 2 has a thermal conductivity of, for example, 50 W/m·K to 350 W/m·K.

The thermal conductivity is determined in conformity with JIS H 7903:2008 (Method For Effective Thermal Conductivity Test).

### (2) First Insulating Layer

The first insulating layer 3 is disposed on one side of the metal support layer 2 in the thickness direction of the metal support layer 2. The first insulating layer 3 is disposed away from the metal support layer 2 in the thickness direction. The first insulating layer 3 is disposed between the conductive pattern 4 and the metal support layer 2 in the thickness direction. The first insulating layer 3 is disposed between the conductive pattern 4 and the heat dissipating layer 6 in the thickness direction. The first insulating layer 3 insulates the metal support layer 2 and the heat dissipating layer 6 from the conductive pattern 4. The first insulating layer 3 is made of polyimide. When the first insulating layer 3 contains fluorine, and the content of fluorine decreases, the water absorption rate of the first insulating layer tends to increase. Preferably, the first insulating layer 3 does not contain fluorine.

The first insulating layer 3 has a water absorption rate of 0.40% or more. When the water absorption rate of the first insulating layer 3 is the above-described lower limit or more, and the heat of molten solder is transferred to the first insulating layer 3 through a terminal 41 of the conductive pattern 4, the first insulating layer 3 may be easily released from the metal support layer 2.

The water absorption rate of the first insulating layer 3 is, for example, 0.80% or less, preferably 0.60% or less.

The first insulating layer 3 has a thickness T1 of, for example, 50 μm or less, preferably 30 μm or less between the terminal 41 of the conductive pattern 4 and the heat dissipating layer 6. When the thickness T1 of the first insulating layer 3 is the above-described upper limit or less, it is possible to suppress the accumulation of the heat of molten solder in the first insulating layer 3, and to smoothly diffuse the heat transferred to the first insulating layer 3 through the terminal 41 into the heat dissipating layer 6.

The thickness T1 of the first insulating layers 3 is, for example, 1 μm or more, preferably 3 μm or more. When the thickness T1 of the first insulating layer 3 is the above-described lower limit or more, the metal support layer 2 and the heat dissipating layer 6 can be insulated from the terminal 41.

### (4) Conductive Pattern

The conductive pattern 4 is disposed on one side of the first insulating layer 3 in the thickness direction. The conductive pattern 4 is disposed on a one-side surface of the first insulating layer 3 in the thickness direction. The conductive pattern 4 is disposed on an opposite side to the metal support layer 2 with respect to the first insulating layer 3 in the thickness direction. The conductive pattern 4 is made of metal. Examples of the metal include, for example, copper, silver, gold, iron, aluminum, chromium, and the alloys thereof. From the viewpoint of obtaining good electrical properties, copper is preferably used. The shape of the conductive pattern 4 is not limited. The conductive pattern 4 includes the terminal 41 and a wire 42.

The terminal 41 is disposed on the one-side surface of the first insulating layer 3 in the thickness direction. The terminal 41 extends in the first direction and the second direction. The terminal 41 has, for example, an approximately rectangular shape (see FIG. 1). The shape of the terminal 41 is not limited. The terminal 41 may have a circular shape. The wiring circuit board 1 may include a plurality of terminals 41. When the wiring circuit board 1 includes a plurality of terminals 41, the plurality of terminals 41 are arranged, for example, in the first direction.

The terminal 41 has a dimension L1 of, for example, 50 μm to 1000 μm, preferably 100 μm to 800 μm in the first direction.

The terminal 41 has a dimension L2 of, for example, 50 μm to 1000 μm, preferably 100 μm to 800 μm in the second direction.

In a direction orthogonal to the thickness direction, the terminal 41 has an area S of, for example, 10000 μm² to 800000 μm², preferably 50000 μm² to 500000 μm².

The dimension L1 and the dimension L2 are the dimensions of an other-side surface (the surface in contact with the first insulating layer 3) of the terminal 41 in the thickness direction. The area of the terminal 41 is the area of the other-side surface (the surface in contact with the first insulating layer 3) of the terminal 41 in the thickness direction.

The ratio (S/T1) of the area S of the terminal 41 to the thickness T1 of the first insulating layer 3 is, for example, 5000 μm or more, preferably 10000 μm or more, and more preferably 20000 μm or more. When the area S of the terminal 41 is large relative to the thickness T1 of the first insulating layer 3, the amount of heat accumulated per unit area of the first insulating layer 3 can be reduced. Further, when the thickness T1 of the first insulating layer 3 is small relative to the area S of the terminal 41, the accumulation of the heat of molten solder in the first insulating layer 3 can be suppressed, and the heat transferred to the first insulating layer 3 through the terminal 41 can be smoothly diffused into the heat dissipating layer 6. The ratio (S/T1) may be, for example, 50000 μm or less, or 30000 μm or less.

The terminal 41 may include a first conductor layer 411 and a second conductor layer 412. The first conductor layer 411 is disposed on the one-side surface of the first insulating layer 3 in the thickness direction. The second conductor layer 412 is disposed on a one-side surface of the first conductor layer 411 in the thickness direction. A one-side surface of the second conductor layer 412 is disposed on one side in the thickness direction as compared with the second insulating layer 5. The terminal 41 may not have a second conductor layer 412.

The wire 42 is connected to the terminal 41. The wire 42 may be connected to the first conductor layer 411 of the terminal 41 or may be connected to the second conductor layer 412 of the terminal 41.

### (5) Second Insulating Layer

The second insulating layer 5 is disposed on the one-side surface of the first insulating layer 3 in the thickness direction. The second insulating layer 5 covers the wire 42. The second insulating layer 5 may cover a peripheral edge portion of the terminal 41. When the terminal 41 includes a first conductor layer 411 and a second conductor layer 412, the second insulating layer 5 may cover a peripheral edge portion of the first conductor layer 411. The second insulating layer 5 does not cover at least a central portion of the terminal 41. When the terminal 41 includes a first conductor layer 411 and a second conductor layer 412, the second insulating layer 5 does not cover the second conductor layer 412. The second insulating layer 5 is made of resin. Examples of the resin include polyimide, maleimide, epoxy resin, polybenzoxazole, and polyester. The second insulating layer 5 is preferably made of polyimide.

### (6) Heat Dissipating Layer

The heat dissipating layer 6 is disposed on one side of the metal support layer 2 in the thickness direction of the metal support layer 2. The heat dissipating layer 6 is disposed on a one-side surface of the metal support layer 2 in the thickness direction. The heat dissipating layer 6 is disposed between the metal support layer 2 and the first insulating layer 3 in the thickness direction. The heat dissipating layer 6 is in contact with both the metal support layer 2 and the first insulating layer 3. The heat dissipating layer 6 is disposed on at least an opposite side to the terminal 41 with respect to the first insulating layer 3 in the thickness direction. In this manner, when the heat of molten solder is transferred to the first insulating layer 3 through the terminal 41, the heat transferred to the first insulating layer 3 can be diffused into the heat dissipating layer 6, and can be transferred to the metal support layer 2 through the heat dissipating layer 6. In this manner, it is possible to suppress the accumulation of the heat of molten solder in the first insulating layer 3. As a result, even when the first insulating layer 3 has a high water absorption rate (the water absorption rate is 0.40% or more), the release of the first insulating layer 3 from the metal support layer 2 can be suppressed. The heat dissipating layer 6 may be disposed on an opposite side to the entire conductive pattern 4 with respect to the first insulating layer 3 in the thickness direction.

The heat dissipating layer 6 extends in a direction orthogonal to the thickness direction. In the direction orthogonal to the thickness direction, the area of the heat dissipating layer 6 is larger than or equal to the area S of the terminal. Therefore, the heat transferred to the first insulating layer 3 through the terminal 41 can be reliably diffused into the heat dissipating layer 6.

The thermal conductivity of the heat dissipating layer 6 is higher than the thermal conductivity of the metal support layer 2. Therefore, the heat transferred to the first insulating layer 3 through the terminal 41 can be smoothly diffused into the heat dissipating layer 6. The heat dissipating layer 6 has a thermal conductivity of, for example, 300 W/m·K or more, preferably 350 W/m·K or more. The thermal conductivity of the heat dissipating layers 6 is, for example, 450 W/m·K or less.

The material of the heat dissipating layer 6 is different from the material of the metal support layer 2. The heat dissipating layer 6 is made of metal. Examples of the metal include copper, silver, aluminum, gold, nickel, and platinum. The heat dissipating layer 6 is preferably made of copper.

A thickness T2 of the heat dissipating layer 6 may be smaller than the thickness of the metal support layer 2. The thickness T2 of the heat dissipating layers 6 is, for example, 0.5 μm or more, preferably 1 μm or more. When the thickness T2 of the heat dissipating layer 6 is the above-described lower limit or more, the volume of the heat dissipating layer 6 can be ensured. Therefore, the heat transferred to the first insulating layer 3 through the terminal 41 can be reliably diffused into the heat dissipating layer 6. The thickness T2 of the heat dissipating layer 6 is, for example, 20 μm or less, preferably 10 μm or less.

### 2. Method of Producing Wiring Circuit Board

Next, a method of producing the wiring circuit board 1 is described.

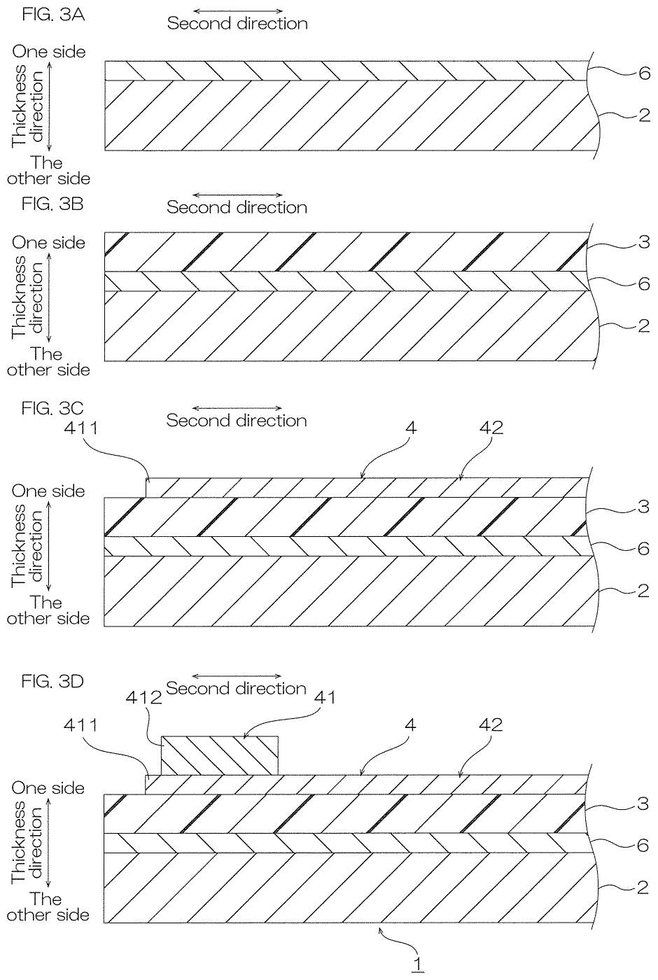

The method of producing the wiring circuit board 1 includes a heat dissipating layer forming step (see FIG. 3A), a first insulating layer forming step (see FIG. 3B), a conductive pattern forming step (see FIG. 3C and FIG. 3D), and a second insulating layer forming step (see FIG. 2).

### (1) Heat Dissipating Layer Forming Step

As shown in FIG. 3A, in the heat dissipating layer forming step, a heat dissipating layer 6 is formed on a one-side surface of a metal support layer 2 in the thickness direction, for example, by electrolytic plating.

(2) First Insulating Layer Forming Step Next, as shown in FIG. 3B, in the first insulating layer forming step, a first insulating layer 3 is formed on a one-side surface of the heat dissipating layer 6 in the thickness direction.

Specifically, first, a solution (varnish) of photosensitive polyimide is applied to the one-side surface of the heat dissipating layer 6 and dried to form a coating film of photosensitive polyimide.

Next, the coating film of photosensitive polyimide is exposed to light and developed. In this manner, a first insulating layer 3 is formed.

### (3) Conductive Pattern Forming Step

Next, as shown in FIGS. 3C and 3D, in the conductive pattern forming step, a conductive pattern 4 is formed on a one-side surface of the first insulating layer 3 in the thickness direction.

As shown in FIG. 3C, in the conductive pattern forming step, first, a first conductor layer 411 of a terminal 41 and a wire 42 are formed.

Specifically, a seed layer is formed on the one-side surface of the first insulating layer 3 in the thickness direction. The seed layer is formed, for example, by sputtering. Examples of the material for the seed layer include, for example, chromium, copper, nickel, titanium, and the alloys thereof.

Next, the one-side surface of the first insulating layer 3 in the thickness direction is covered with a first plating resist.

Next, the first plating resist is exposed to light and developed. Then, the first plating resist in the portion where the first conductor layer 411 of the terminal 41 and the wire 42 are to be formed is removed, and the seed layer is exposed in the portion where the first conductor layer 411 of the terminal 41 and the wire 42 are to be formed. On the other hand, the first plating resist remains in the portion where the first conductive layer 411 of the terminal 41 and the wire 42 are not formed.

Next, the first conductor layer 411 of the terminal 41 and the wire 42 are formed on the exposed seed layer by electrolytic plating. After the electrolytic plating is completed, the first plating resist is released therefrom.

Next, as shown in FIG. 3D, in the conductive pattern forming step, a second conductor layer 412 of the terminal 41 is formed.

Specifically, the one-side surface of the first insulating layer 3 in the thickness direction, the first conductor layer 411, and the wire 42 are covered with a second plating resist.

Next, the second plating resist is exposed to light and developed. Then, the second plating resist in the portion where the second conductor layer 412 is to be formed is removed, and the first conductor layer 411 is exposed in the portion where the second conductor layer 412 is to be formed. On the other hand, the second plating resist remains in the portion where the second conductor layer 412 is not formed.

Next, the second conductor layer 412 is formed on the exposed first conductor layer 411 by electrolytic plating. After the electrolytic plating is completed, the second plating resist is released therefrom. Thereafter, the seed layer exposed by the release of the second plating resist is removed by etching.

As described above, a conductive pattern 4 is formed.

### (4) Second Insulating Layer Forming Step

Next, as shown in FIG. 2, in the second insulating layer forming step, a second insulating layer 5 is formed on the one-side surface of the first insulating layer 3 in the thickness direction.

Specifically, in the second insulating layer forming step, first, a solution (varnish) of a photosensitive resin is applied to the conductive pattern 4 and the first insulating layer 3 and dried to form a coating film of the photosensitive resin.

Next, the coating film of the photosensitive resin is exposed to light and developed. In this manner, a second insulating layer 5 is formed on the first insulating layer 3.

### 3. Operations and Effects

As shown in FIG. 2, the wiring circuit board 1 includes the heat dissipating layer 6 between the metal support layer 2 and the first insulating layer 3.

Therefore, when the heat of molten solder is transferred to the first insulating layer 3 through the terminal 41, the heat transferred to the first insulating layer 3 can be diffused into the heat dissipating layer 6, and can be transferred to the metal support layer 2 through the heat dissipating layer 6.

Therefore, it is possible to suppress the accumulation of the heat of molten solder in the first insulating layer 3.

As a result, even when the first insulating layer 3 has a high water absorption rate (the water absorption rate is 0.40% or more), the release of the first insulating layer 3 from the metal support layer 2 can be suppressed.

### EXAMPLES

With reference to Examples and Comparative Examples below, the present invention is more specifically described. The present invention is not limited to Examples and Comparative Examples in any way. The specific numeral values used in the description below, such as blending ratios (content ratios), physical property values, and parameters, can be replaced with the corresponding blending ratios (content ratios), physical property values, and parameters in the above-described “DESCRIPTION OF THE EMBODIMENT”, including the upper limit values (numeral values defined with “or less” or “less than”) or the lower limit values (numeral values defined with “or more” or “more than”).

### 1. Production of Wiring Circuit Board

### (1) Example 1

First, a metal support layer made of a copper alloy was prepared.

Next, a heat dissipating layer was formed on a one-side surface of the metal support layer by electrolytic plating (heat dissipating layer forming step).

Next, a solution (varnish) of photosensitive polyimide was applied on a surface of the heat dissipating layer and dried. In this manner, a coating film of photosensitive polyimide was formed on the surface of the heat dissipating layer.

Next, the coating film of the photosensitive polyimide was exposed to light and developed. In this manner, a first insulating layer made of polyimide was formed on the surface of the heat dissipating layer (first insulating layer forming step).

Next, a seed layer made of chromium was formed on the first insulating layer by sputtering.

Next, the first insulating layer was covered with a first plating resist, and the first plating resist was exposed to light and developed. Then, the first plating resist in the portion where a first conductive layer of a terminal and a wire were to be formed was removed, and the seed layer was exposed in the portion where the first conductive layer and the wire were to be formed.

Next, a first conductor layer made of copper and a wire made of copper were formed on the exposed seed layer by electrolytic plating. After the electrolytic plating was completed, the first plating resist was released therefrom.

Next, the first insulating layer, the first conductor layer, and the wire were covered with a second plating resist, and the second plating resist was exposed to light and developed. Then, the second plating resist in the portion where a second conductor layer of the terminal was to be formed was removed, and the first conductor layer was exposed in the portion where the second conductor layer was to be formed.

Next, a second conductor layer was formed on the exposed first conductor layer by electrolytic plating. After the electrolytic plating was completed, the second plating resist was released therefrom, and the seed layer exposed by the release of the second plating resist was removed by etching. In this manner, and a conductive pattern was formed on the first insulating layer (conductive pattern forming step).

Next, a solution (varnish) of photosensitive polyimide was applied onto the first insulating layer and the conductive pattern and dried to form a coating film of photosensitive polyimide.

Next, the coating film of the photosensitive polyimide was exposed to light and developed. In this manner, a second insulating layer was formed on the first insulating layer (second insulating layer forming step). As described above, a wiring circuit board was produced.

The ratio (S/T1) of the area of the terminal to the thickness of the first insulating layer was 26042.

### (2) Example 2

Except that a photosensitive polyimide having a water absorption rate of 0.49% was used, a wiring circuit board having a conductive pattern in the same shape as that of the conductive pattern of Example 1 was produced in the same manner as in Example 1.

### (3) Comparative Example 1

Except that a photosensitive polyimide having a water absorption rate of 0.38% was used, a wiring circuit board having a conductive pattern in the same shape as that of the conductive pattern of Example 1 was produced in the same manner as in Example 1.

### (4) Comparative Example 2

Except that a photosensitive polyimide having a water absorption rate of 0.38% was used, and a heat dissipating layer was not formed, a wiring circuit board having a conductive pattern in the same shape as that of the conductive pattern of Example 1 was produced in the same manner as in Example 1.

### (5) Comparative Example 3

Except that a heat dissipating layer was not formed, a wiring circuit board having a conductive pattern in the same shape as that of the conductive pattern of Example 1 was produced in the same manner as in Example 1.

### (6) Comparative Example 4

Except that a heat dissipating layer was not formed, a wiring circuit board having a conductive pattern in the same shape as that of the conductive pattern of Example 1 was produced in the same manner as in Example 2.

### 2. Physical Property Measurement

### (1) Water Absorption Rate of First Insulating Layer

The water absorption rate of the first insulating layer of the wiring circuit board produced in each Example and each Comparative Example was measured by the following method. The results are shown in Table 1.

Using a thermogravimetric-differential thermal analyzer (TG-DTA), the temperature was increased from a room temperature (25° C.) to 100° C. at a rate of temperature increase of 5° C./min, and the reduction ratio of a mass M2 of the first insulating layer at 100° C. to a mass M1 of the first insulating layer at a room temperature (25° C.) was calculated as the water absorption rate according to the following formula.

$$Water Absorption Rate ( \% ) = ( M 1 - M 2 ) / M 1 \times 100 \qquad Formula$$

### (2) Shear Strength

The shear strength of the first insulating layer of the wiring circuit board produced in each Example and each Comparative Example was measured.

Specifically, solder was disposed on the one-side surface of the second conductive layer of the terminal in the thickness direction (see FIG. 2), and the solder was heated and melted using a laser of a power of 0.15 J.

Next, a shear force along the second direction (see FIG. 2) was applied to the first insulating layer by using a blade. The shear force being applied when the first insulating layer is released from the heat dissipating layer or from the metal support layer is defined as the shear strength. The measured share strengths are shown in Table 1.

TABLE 1

| | | | Comp. | Comp. | Comp. | Comp. |
|---|---|---|---|---|---|---|
| | Example 1 | Example 2 | Ex. 1 | Ex. 2 | Ex. 3 | Ex. 4 |
| Heat dissipating layer | Presence | Presence | Presence | Absence | Absence | Absence |
| Water absorption rate (%) | 0.65 | 0.49 | 0.38 | 0.38 | 0.65 | 0.49 |
| S/T1 (μm) | 26042 | 26042 | 26042 | 26042 | 26042 | 26042 |
| Shear strength (g/mm) | 2196 | 2304 | 2247 | 2293 | 1485 | 1851 |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
2 Metal support layer
6 Heat dissipating layer
41 Terminal

1. A wiring circuit board comprising:
a metal support layer;
an insulating layer disposed on one side of the metal support layer in a thickness direction of the metal support layer, the insulating layer being made of polyimide, and the insulating layer having a water absorption rate of 0.40% or more;
a terminal disposed on a one-side surface of the insulating layer in the thickness direction; and
a heat dissipating layer disposed on an opposite side to the terminal with respect to the insulating layer in the thickness direction, the heat dissipating layer being disposed between the metal support layer and the insulating layer in the thickness direction, and the heat dissipating layer being in contact with both the metal support layer and the insulating layer.

2. The wiring circuit board according to claim 1,
wherein an area of the heat dissipating layer is larger than or equal to an area of the terminal in a direction orthogonal to the thickness direction.

3. The wiring circuit board according to claim 1,
wherein a thermal conductivity of the heat dissipating layer is higher than a thermal conductivity of the metal support layer.

4. The wiring circuit board according to claim 1,
wherein the heat dissipating layer has a thickness of 0.5 μm or more.

5. The wiring circuit board according to claim 1,
wherein the insulating layer has a thickness of 50 μm or less between the terminal and the heat dissipating layer.

6. The wiring circuit board according to claim 1,
wherein a ratio of the area of the terminal in the direction orthogonal to the thickness direction to a thickness of the insulating layer is 5000 μm or more.
